(19) United States
(12) Patent Application Publication
(10) Pub. No.: US 2024/0260390 A1
(43) Pub. Date: Aug. 1, 2024

(54) DISPLAY DEVICE

(71) Applicant: Samsung Display Co., Ltd., Yongin-Si (KR)

(72) Inventors: KEUMHEE LEE, Yongin-si (KR); DONGHAN KANG, Yongin-si (KR); JEEHOON KIM, Yongin-si (KR); SUNGGWON MOON, Yongin-si (KR); SEUNGSOK SON, Yongin-si (KR); SHINHYUK YANG, Yongin-si (KR); KAP SOO YOON, Yongin-si (KR); WOOGEUN LEE, Yongin-si (KR)

(21) Appl. No.: 18/512,016

(22) Filed: Nov. 17, 2023

(30) Foreign Application Priority Data
Jan. 26, 2023 (KR) 10-2023-0010146

(51) Int. Cl. H10K 59/80; H10K 59/122; H10K 59/126; H10K 59/131

(52) U.S. Cl. CPC H10K 59/80516; H10K 59/122; H10K 59/126; H10K 59/131

(57) ABSTRACT

A display device comprises: a first auxiliary electrode, a second auxiliary electrode, an interlayer insulating layer exposing at least a portion of the second auxiliary electrode, and defining a first through-hole including a first side area and a second side area, a third auxiliary electrode, a passivation layer disposed on the third auxiliary electrode, exposing at least a portion of the third auxiliary electrode, and including a second through-hole including a first side area and a second side area, a pixel defining layer including a third through-hole.

### CROSS-REFERENCE TO RELATED APPLICATION(S)

This application claims priority to and benefits of Korean Patent Application No. 10-2023-0010146 under 35 U.S.C. § 119, filed on Jan. 26, 2023, in the Korean Intellectual Property Office (KIPO), the entire contents of which are incorporated herein by reference.

### BACKGROUND

### 1. Technical Field

Embodiments relate to a display device.

### 2. Description of the Related Art

A display device may include a plurality of pixels, and each of the plurality of pixels may emit light. Each of the plurality of pixels may include a light emitting layer that emits light, a pixel electrode and a common electrode that provide an electrical signal to the light emitting layer.

To provide the electrical signal, the common electrode may include a conductive material. In this case, a display quality of the display device may be deteriorated due to voltage drop (IR drop) of the common electrode.

### SUMMARY

Embodiments provide a display device with improved display quality.

A display device according to an embodiment includes a first auxiliary electrode, a second auxiliary electrode disposed on the first auxiliary electrode, an interlayer insulating layer disposed on the second auxiliary electrode, exposing at least a portion of the second auxiliary electrode, and including a first through-hole which includes a first side area and a second side area, a third auxiliary electrode covering the second auxiliary electrode exposed by the first through-hole and a portion of the interlayer insulating layer, the third auxiliary electrode including a first inclined surface and a second inclined surface, a passivation layer disposed on the third auxiliary electrode, exposing at least a portion of the third auxiliary electrode, and including a second through-hole which includes a first side area and a second side area, a pixel defining layer disposed on the passivation layer and defining a third through-hole, the third through-hole including a first side area and a second side area, a light emitting layer disposed on the pixel defining layer and the third auxiliary electrode, and a common electrode disposed on the light emitting layer.

In an embodiment, an undercut space may be defined by the second side area of the second through-hole and a lower surface of the pixel defining layer in the second through-hole.

In an embodiment, the common electrode may be electrically connected to the third auxiliary electrode in the undercut space.

In an embodiment, the second side area of the first through-hole, the second side area of the second through-hole, the second side area of the third through-hole, and the second inclined surface of the third auxiliary electrode may partially overlap the undercut space.

In an embodiment, the second side area of the second through-hole may be disposed further away from a central portion of the first through-hole than the first side area of the second through-hole.

In an embodiment, the first side area of the second through-hole may be disposed closer to a central portion of the first through-hole than the first side area of the first through-hole.

In an embodiment, the second side area of the third through-hole may be disposed further away from a central portion of the first through-hole than the first side area of the third through-hole.

In an embodiment, the first side area of the third through-hole may be disposed closer to a central portion of the first through-hole than the first side area of the second through-hole.

In an embodiment, the second side area of the first through-hole may intersect the second side area of the third through-hole in a plan view.

In an embodiment, the second side area of the first through-hole may intersect the second side area of the third through-hole in an acute angle in a plan view.

In an embodiment, the display device may further include a buffer layer disposed between the first auxiliary electrode and the second auxiliary electrode.

In an embodiment, the display device may further include an auxiliary electrode insulating layer disposed between the buffer layer and the second auxiliary electrode.

In an embodiment, the third auxiliary electrode and the first auxiliary electrode may be connected to each other by a contact hole.

In an embodiment, the common electrode may be in contact with the second inclined surface of the third auxiliary electrode.

A display device according to another embodiment includes a first auxiliary electrode, a buffer layer including a first through-hole exposing at least a portion of the first auxiliary electrode, an interlayer insulating layer disposed on the buffer layer, including a second through-hole overlapping the first through-hole, a second auxiliary electrode covering the first auxiliary electrode exposed by the first through-hole and the second through-hole, a portion of the buffer layer, and a portion of the interlayer insulating layer, wherein the second auxiliary electrode include a first inclined surface and a second inclined surface, a passivation layer disposed on the second auxiliary electrode, exposing at least a portion of the second auxiliary electrode, and including a third through-hole which includes a first side area and a second side area, a pixel defining layer disposed on the passivation layer, including a fourth through-hole, the fourth through-hole including a first side area and a second side area, a light emitting layer disposed on the pixel defining layer and the second auxiliary electrode, and a common electrode disposed on the light emitting layer. The undercut space may be defined by the second side of the third through-hole and a lower surface of the pixel defining layer in the third through-hole. The common electrode may be electrically connected to the second auxiliary electrode in the undercut space. The second side area of the first through-hole, the second side area of the second through-hole, the second side area of the third through-hole, the second side area of the fourth through-hole, and the second inclined surface of the second auxiliary electrode may partially overlap the undercut space.

In an embodiment, the second through-hole may have a first side area and a second side area.

In an embodiment, the second auxiliary electrode may include a first inclined surface and a second inclined surface.

In an embodiment, the undercut space may be spaced apart from the second inclined surface of the second auxiliary electrode to expose the second side area of the passivation layer and the fourth through-hole may include a first side area and a second side area.

In an embodiment, the second side area of the first through-hole, the second side area of the second through-hole, the second side area of the third through-hole, the second side area of the fourth through-hole, and the second inclined surface of the second auxiliary electrode may partially overlap the undercut space.

In an embodiment, the second side area of the third through-hole may be disposed further from a central portion of the first through-hole than the first side area of the third through-hole.

In an embodiment, the first side area of the third through-hole may be disposed closer to a central portion of the first through-hole than the first side area of the second through-hole.

In an embodiment, the second side area of the fourth through-hole may be disposed further from a central portion of the first through-hole than the first side area of the fourth through-hole.

In an embodiment, the first side area of the fourth through-hole may be disposed closer to a central portion of the first through-hole than the first side area of the third through-hole.

In an embodiment, the second side area of the second through-hole may intersect the second side area of the fourth through-hole in a plan view.

In an embodiment, the second side area of the second through-hole may intersect the second side area of the fourth through-hole in an acute angle in a plan view.

In an embodiment, the common electrode may be in contact with the second inclined surface of the second auxiliary electrode.

In an embodiment, the first auxiliary electrode and the second auxiliary electrode may be connected to each other by a contact hole.

A display device according to an embodiment includes a first auxiliary electrode, a second auxiliary electrode disposed on the first auxiliary electrode, an interlayer insulating layer disposed on the second auxiliary electrode, exposing at least a portion of the second auxiliary electrode, and including a first through-hole which includes a first side area and a second side area, a third auxiliary electrode covering the second auxiliary electrode exposed by the first through-hole and a portion of the interlayer insulating layer, a third auxiliary electrode including a first inclined surface and a second inclined surface, a passivation layer disposed on the third auxiliary electrode, exposing at least a portion of the third auxiliary electrode, and including a second through-hole which includes a first side area and a second side area, a pixel defining layer disposed on the passivation layer and including a third through-hole, wherein the third through-hole includes a first side area and a second side area, a light emitting layer disposed on the pixel defining layer and the third auxiliary electrode, and a common electrode disposed on the light emitting layer. An undercut space may be defined by the second side area of the second through-hole and a lower surface of the pixel defining layer in the second through-hole. The common electrode may be electrically connected to the third auxiliary electrode in the undercut space.

Accordingly, a voltage drop phenomenon of the common electrode may be prevented.

### BRIEF DESCRIPTION OF THE DRAWINGS

Illustrative, non-limiting embodiments will be more clearly understood from the following detailed description in conjunction with the accompanying drawings.

FIG. 1 is a schematic plan view illustrating a display device according to an embodiment.

FIG. 2 is a schematic cross-sectional view of the display device of FIG. 1 cut along an X-Y line.

FIG. 3 is an schematic enlarged cross-sectional view of a non-light emitting area included in the display device of FIG. 2.

FIGS. 4, 5, 6, 7, 8, 9, and 10 are schematic cross-sectional views illustrating a method of manufacturing the display device of FIG. 1.

FIG. 11A is a schematic plan view of an interlayer insulating layer according to a comparative example.

FIG. 11B is a schematic plan view illustrating a pixel defining layer of FIG. 2.

FIG. 12A is a schematic plan view illustrating a first relative position of the pixel defining layer of FIG. 11B and the interlayer insulating layer according to comparative example.

FIG. 12B is a schematic cross-sectional view of display device cut along the I-I′ line of FIG. 12A.

FIG. 13A is a schematic plan view illustrating a second relative position of the pixel defining layer of FIG. 11B and the interlayer insulating layer according to comparative example.

FIG. 13B is a schematic cross-sectional view of display device cut along the I-I′ line of FIG. 13A.

FIG. 14A is a schematic plan view illustrating a third relative position of the pixel defining layer of FIG. 11B and the interlayer insulating layer according to comparative example.

FIG. 14B is a schematic cross-sectional view of display device cut along the I-I′ line of FIG. 14A.

FIG. 15A is a schematic plan view illustrating an interlayer insulating layer according to an embodiment.

FIG. 15B is a schematic plan view illustrating a pixel defining layer according to an embodiment.

FIG. 16 is a schematic plan view illustrating that the pixel defining layer of FIG. 15B is disposed on the interlayer insulating layer of FIG. 15A.

FIG. 17 is a schematic cross-sectional view illustrating a non-light emitting area of a display device according to another embodiment.

FIG. 18 is a schematic plan view illustrating an interlayer insulating layer and a pixel defining layer of FIG. 17.

### DETAILED DESCRIPTION OF THE EMBODIMENTS

Hereinafter, display devices in accordance with embodiments will be described in more detail with reference to the accompanying drawings. The same reference numerals are used for the same components in the drawings, and redundant descriptions of the same components will be omitted.

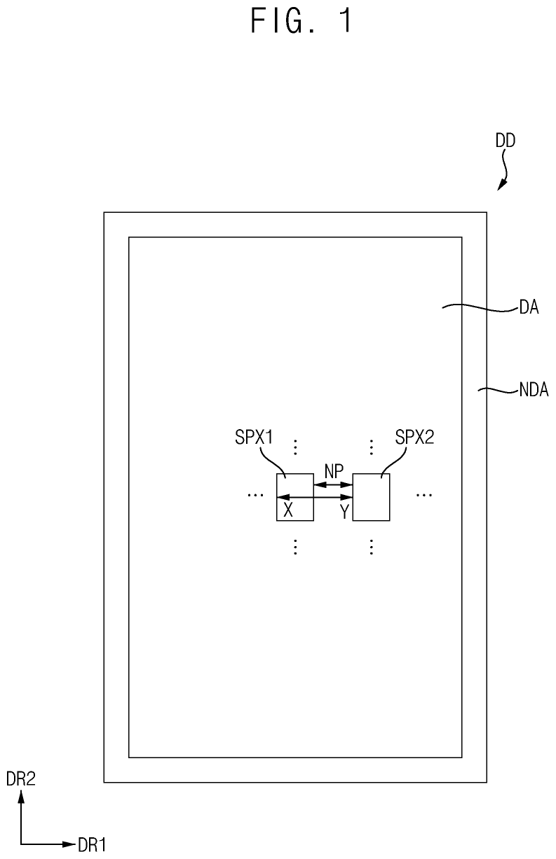

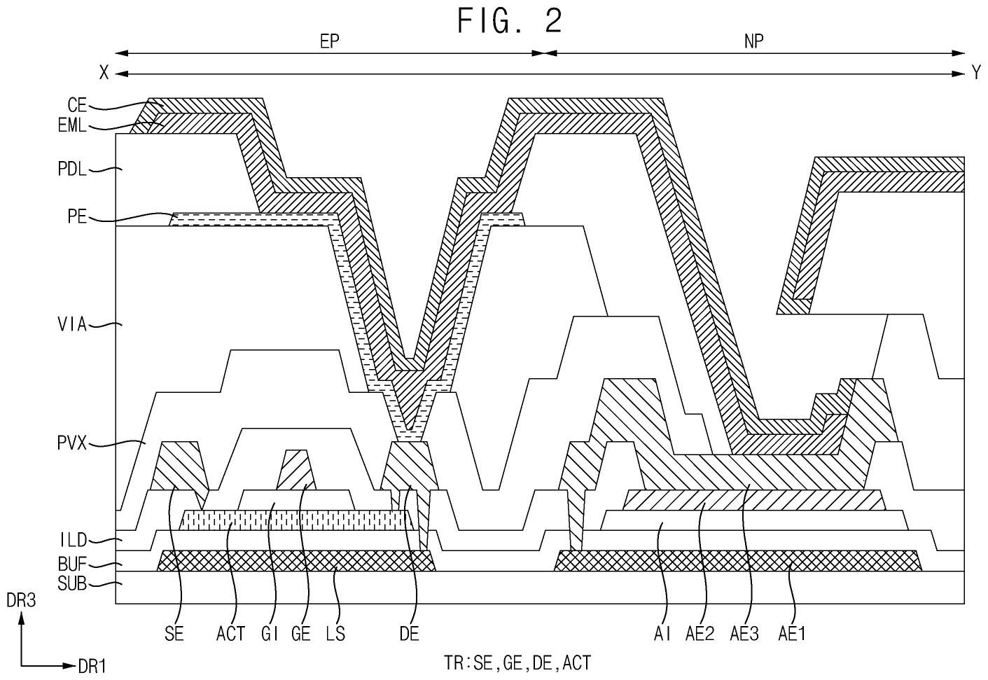

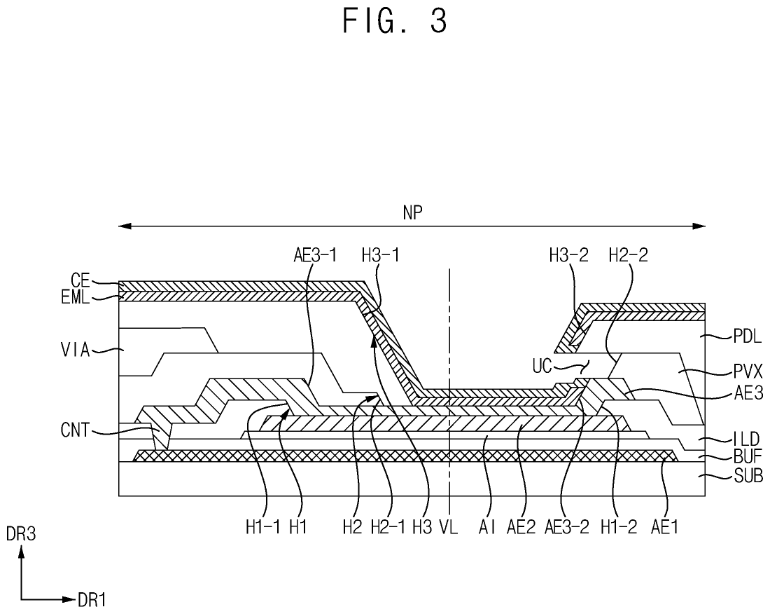

FIG. 1 is a schematic plan view illustrating a display device according to an embodiment. FIG. 2 is a schematic cross-sectional view of the display device of FIG. 1 cut along an X-Y line. FIG. 3 is an schematic enlarged cross-sectional view of a non-light emitting area included in the display device of FIG. 2.

In this specification, a plane may be defined by a first direction DR1 and a second direction DR2 crossing the first direction DR1, and for example, the first direction DR1 and the second direction DR2 may be perpendicular to each other. In addition, the third direction DR3 may be perpendicular to each of the first direction DR1 and the second direction DR2.

Referring to FIGS. 1 and 2, a display device DD may include a display area DA and a non-display area NDA. The display area DA may be defined as an area that emits light, and the non-display area NDA may be defined as an area in which configurations for transmitting a signal transmitted to the display area DA are disposed.

The display area DA may include a plurality of pixel areas. The plurality of pixel areas may include a first pixel area SPX1 and a second pixel area SPX2. Each of the first pixel area SPX1 and the second pixel area SPX2 may refer to an area in which light emitted from a light emitting element is emitted to outside of the display device DD. For example, each of the plurality of pixel areas may include a light emitting area EP.

The plurality of pixel areas may be repeatedly arranged along the first direction DR1 and the second direction DR2 crossing the first direction DR1 in a plan view. For example, the second pixel area SPX2 may be adjacent to the first pixel area SPX1. Specifically, the second pixel area SPX2 may be disposed adjacent to the first pixel area SPX1 in the first direction DR1.

A non-light emitting area NP may be disposed between adjacent pixel areas of the plurality of pixel areas. For example, the non-light emitting area NP may be disposed between the first pixel area SPX1 and the second pixel area SPX2.

The non-display area NDA may be disposed around the display area DA. For example, the non-display area NDA may surround at least a portion of the display area DA. A driving unit may be disposed in the non-display area NDA. The driving unit may provide a signal or a voltage to the plurality of pixel areas. For example, the driving unit may include a data driving unit, a gate driving unit, or the like. The non-display area NDA may not display an image.

In the light emitting area EP, a substrate SUB, a buffer layer BUF, a light blocking layer LS, a gate insulating layer GI, an interlayer insulating layer ILD, a transistor TR, a passivation layer PVX, a via insulating layer VIA, a pixel electrode PE, a pixel defining layer PDL, a light emitting layer EML, and a common electrode CE may be disposed. Here, the transistor TR may include an active pattern ACT, a gate electrode GE, a source electrode SE, and a drain electrode DE.

The substrate SUB may include a transparent material or an opaque material. The substrate SUB may be formed of a transparent resin substrate. Examples of the transparent resin substrate may include a polyimide substrate. In this case, the polyimide substrate may include a first organic layer, a first barrier layer, a second organic layer, or the like.

Alternatively, the substrate SUB may include a quartz substrate, a synthetic quartz substrate, a calcium fluoride substrate, a fluorine-doped quartz substrate, a soda lime substrate, a non-alkali glass substrate, or the like. These materials may be used alone or in combination with each other.

The light blocking layer LS may be disposed on the substrate SUB. The light blocking layer LS may block external light from being incident, thereby preventing generation of photoelectric current in the transistor TR.

The buffer layer BUF may be disposed on the substrate SUB and the light blocking layer LS. The buffer layer BUF may prevent metal atoms or impurities from diffusing from the substrate SUB to the transistor TR. In addition, the buffer layer BUF can improve flatness of a surface of the substrate SUB when the surface of the substrate SUB is not uniform.

For example, the buffer layer BUF may include an inorganic material such as silicon oxide, silicon nitride, silicon oxynitride, or the like. These materials may be used alone or in combination with each other. The buffer layer BUF may include a contact hole exposing at least a portion of the light blocking layer LS in some areas.

The active pattern ACT may be disposed on the buffer layer BUF. The active pattern ACT may include a metal oxide semiconductor, an inorganic semiconductor (e.g., amorphous silicon, polysilicon), or an organic semiconductor. The active pattern ACT may include a source area, a drain area, and a channel area disposed between the source area and the drain area.

The metal oxide semiconductor may include a binary compound (“ABₓ”), a ternary compound (“ABₓC_{y}”), a tetragonal compound (“ABₓC_{y}D_{z}”), or the like containing indium (“In”), zinc (“Zn”), gallium (“Ga”), tin (“Sn”), titanium (“Ti”), aluminum (“AI”), hafnium (“Hf”), zirconium (“Zr”), magnesium (“Mg”), or the like.

For example, the metal oxide semiconductor may include zinc oxide (“ZnOₓ”), gallium oxide (“GaOₓ”), tin oxide (“SnOₓ”), indium oxide (“InOₓ”), indium gallium oxide (“IGO”), indium zinc oxide (“IZO”), indium tin oxide (“ITO”), indium zinc tin oxide (“IZTO”), indium gallium zinc oxide (“IGZO”), or the like. These materials may be used alone or in combination with each other.

The gate insulating layer GI may be disposed on the active pattern ACT. The gate insulating layer GI may cover at least a portion of the active pattern ACT. Alternatively, the gate insulating layer GI may cover the active pattern ACT and may be disposed along a profile of the active pattern ACT.

For example, the gate insulating layer GI may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), or the like. These materials may be used alone or in combination with each other.

The gate electrode GE may be disposed on the active pattern ACT. The gate electrode GE may overlap the channel area of the active pattern ACT. The channel area of the active pattern ACT may be activated in response to a signal applied to the gate electrode GE.

The gate electrode GE may include a metal, an alloy metal nitride, a conductive metal oxide, a transparent conductive material, or the like. These materials may be used alone or in combination with each other.

Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in combination with each other.

Examples of the conductive metal oxide may include Indium tin oxide, indium zinc oxide, or the like. These materials may be used alone or in combination with each other.

In addition, Examples of the metal nitride may include aluminum nitride (“AlNₓ”), tungsten nitride (“WNₓ”), chromium nitride (“CrNₓ”), or the like. These materials may be used alone or in combination with each other.

The interlayer insulating layer ILD may be disposed on the gate electrode GE. The interlayer insulating layer ILD may sufficiently cover the gate electrode GE. For example, the interlayer insulating layer ILD may cover the gate electrode GE and may be disposed along a profile of the gate electrode GE. In addition, the interlayer insulating layer ILD may include a contact hole exposing at least a portion of the active pattern ACT and the light blocking layer LS in some areas.

For example, the interlayer insulating layer ILD may include inorganic materials such as silicon oxide, silicon nitride, silicon carbide, silicon oxynitride, silicon oxynitride, or the like. These materials may be used alone or in combination with each other.

The source electrode SE may be disposed on the interlayer insulating layer ILD. The source electrode SE may be connected to the source area of the active pattern ACT through the contact hole formed through the interlayer insulating layer ILD.

The drain electrode DE may be disposed on the interlayer insulating layer ILD. The drain electrode DE may be connected to the drain area of the active pattern ACT through the contact hole formed through the interlayer insulating layer ILD. In addition, the drain electrode DE may be connected to the light blocking layer LS through the contact hole formed through the interlayer insulating layer ILD and the buffer layer BUF.

For example, the source electrode SE may include a metal, an alloy, a metal nitride, a conductive metal oxide, a transparent conductive material, or the like. These materials may be used alone or in combination with each other. The drain electrode DE may be formed through the same process as the source electrode SE and may include the same material.

The passivation layer PVX may be disposed on the interlayer insulating layer ILD. The passivation layer PVX may sufficiently cover the source electrode SE and the drain electrode DE. The passivation layer PVX may protect lower layers including the source electrode SE and the drain electrode DE.

The passivation layer PVX may include an inorganic insulating material. Examples of materials that can be used as the passivation layer PVX may include silicon oxide (“SiOₓ”), silicon nitride (“SiNₓ”), silicon oxynitride (“SiON”), or the like. These materials may be used alone or in combination with each other.

The via insulating layer VIA may be disposed on the passivation layer PVX. The via insulating layer VIA may include an organic material. For example, the via insulating layer VIA may include organic materials such as phenolic resin, acrylic resin, polyimide resin, polyamide resin, siloxane resin, epoxy resin, or the like. These materials may be used alone or in combination with each other.

The pixel electrode PE may be disposed on the via insulating layer VIA. The pixel electrode PE may be connected to the drain electrode DE through a contact hole formed through the via insulating layer VIA and the passivation layer PVX.

The pixel electrode PE may include a metal, an alloy, a metal nitride, a conductive metal oxide, a transparent conductive material, or the like. These materials may be used alone or in combination with each other. In an embodiment, the pixel electrode PE may have a stacked structure including ITO/Ag/ITO. The pixel electrode PE may be an anode of a light emitting element.

A pixel defining layer PDL may be disposed on the via insulating layer VIA. The pixel defining layer PDL may cover side portions of the pixel electrode PE. In addition, an opening exposing a portion of an upper surface of the pixel electrode PE may be defined in the pixel defining layer PDL.

For example, the pixel defining layer PDL may include an inorganic material or an organic material. In an embodiment, the pixel defining layer PDL may include an organic material such as an epoxy resin, a siloxane resin, or the like. These materials may be used alone or in combination with each other. In another embodiment, the pixel defining layer PDL may further include a light blocking material containing a black pigment, a black dye, or the like.

The light emitting layer EML may be disposed on the pixel electrode PE. For example, a portion of the light emitting layer EML overlapping the light emitting area EP may include a hole injection layer, a hole transport layer disposed on the hole injection layer, an organic layer disposed on the hole transport layer, an electron transport layer disposed on the organic layer, and an electron injection layer disposed on the electron transport layer. However, this disclosure is not limited thereto, and a portion of the light emitting layer EML overlapping the light emitting area EP may further include other components such as an electron blocking layer, a hole blocking layer, or the like.

The common electrode CE may be disposed on the light emitting layer EML and the pixel defining layer PDL. The common electrode CE may include a metal, an alloy, a metal nitride, a conductive metal oxide, a transparent conductive material, or the like. These materials may be used alone or in combination with each other. The common electrode CE may be a cathode of the light emitting element.

The pixel electrode PE, the light emitting layer EML, and the common electrode CE may constitute the light emitting element.

Referring to FIGS. 2 and 3, a substrate SUB, a first auxiliary electrode AE1, a buffer layer BUF, an auxiliary electrode insulating layer AI, a second auxiliary electrode AE2, a third auxiliary electrode AE3, an interlayer insulating layer ILD, a passivation layer PVX, a pixel defining layer PDL, a contact hole CNT, a light emitting layer EML, and a common electrode CE may be disposed in the non-light emitting area NP.

In describing the non-light emitting area NP, the same sign is assigned to a configuration substantially the same as the light emitting area EP, and the detailed description thereof may be omitted.

The first auxiliary electrode AE1 may be disposed on the substrate SUB. The first auxiliary electrode AE1 may include the same material as the light blocking layer LS of the light emitting area EP, and may be formed through the same process as the light blocking layer LS of the light emitting area EP. The first auxiliary electrode AE1 may be a portion of a power supply voltage line (not shown). Specifically, the first auxiliary electrode AE1 may be a portion of ELVSS line.

The buffer layer BUF may be disposed on the first auxiliary electrode AE1. The buffer layer BUF may sufficiently cover the first auxiliary electrode AE1.

The auxiliary electrode insulating layer AI may be disposed on the buffer layer BUF. The auxiliary electrode insulating layer AI may include the same material as the gate insulating layer GI of the light emitting area EP, and may be formed through the same process as the gate insulating layer GI of the light emitting area EP.

The second auxiliary electrode AE2 may be disposed on the auxiliary electrode insulating layer AI. The second auxiliary electrode AE2 may include the same material as the gate electrode GE of the light emitting area EP, and may be formed through the same process as the gate electrode GE of the light emitting area EP.

The interlayer insulating layer ILD may be disposed on the second auxiliary electrode AE2. The interlayer insulating layer ILD may include a first through-hole H1. The first through-hole H1 may expose at least a portion of the second auxiliary electrode AE2. For example, the first through-hole H1 may expose a central portion of the second auxiliary electrode AE2. The first through-hole H1 may include a first side area H1-1 and a second side area H1-2. The second side area H1-2 may partially overlap an undercut space UC to be described later in a plan view.

The third auxiliary electrode AE3 may cover the second auxiliary electrode AE2 exposed by the first through-hole H1 and a portion of the interlayer insulating layer ILD. For example, the third auxiliary electrode AE3 may cover a portion of the interlayer insulating layer ILD disposed adjacent to the second auxiliary electrode AE2 exposed by the first-through hole H1. The third auxiliary electrode AE3 may include a first inclined surface AE3-1 and a second inclined surface AE3-2. The second inclined surface AE3-2 may partially overlap the undercut space UC in a plan view.

The third auxiliary electrode AE3 may include the same material as the source electrode SE and the drain electrode DE of the light emitting area EP, and may be formed through the same process as the source electrode SE and the drain electrode DE of the light emitting area EP. The third auxiliary electrode AE3 may be connected to the first auxiliary electrode AE1 by the contact hole CNT formed through the interlayer insulating layer ILD and the buffer layer BUF.

The passivation layer PVX may be disposed on the third auxiliary electrode AE3. The passivation layer PVX may include a second through-hole H2. The second through-hole H2 may expose at least a portion of the third auxiliary electrode AE3. The second through-hole H2 may include a first side area H2-1 and a second side area H2-2. The second side area H2-2 may partially overlap the undercut space UC.

The via insulating layer VIA may be disposed on the passivation layer PVX. For example, the via insulating layer VIA may be disposed at a portion overlapping the contact hole CNT on the passivation layer PVX.

The pixel defining layer PDL may be disposed on the passivation layer PVX and the via insulating layer VIA. The pixel defining layer PDL may include a third through-hole H3. The third through-hole H3 may include a first side area H3-1 and a second side area H3-2.

The undercut space UC may be defined by the second side area H2-2 of the second through-hole H2 and a lower surface of the pixel defining layer PDL in the second through-hole H2. For example, the undercut space UC may be a space formed by the lower surface of the pixel defining layer PDL, the second side area H2-2 of the passivation layer PVX, and an upper surface of the third auxiliary electrode AE3. In other words, the undercut space UC may be a region in which the passivation layer PVX is recessed from the second side area H3-2 of the pixel defining layer PDL. The undercut space UC may expose the second side area H2-2 of the passivation layer PVX.

The light emitting layer EML may be disposed on the pixel defining layer PDL and the third auxiliary electrode AE3. A portion of the light emitting layer EML overlapping the non-light emitting area NP may include the hole injection layer, the hole transport layer disposed on the hole injection layer, the electron transport layer disposed on the hole transport layer, and the electron injection layer disposed on the electron transport layer.

The common electrode CE may be disposed on the light emitting layer EML. A space in which the common electrode CE contacts the third auxiliary electrode AE3 may be formed through the undercut space UC. Specifically, the common electrode CE may be in contact with the second inclined surface AE3-2 of the third auxiliary electrode AE3.

In an embodiment, each of the light emitting layer EML and the common electrode CE may be disconnected in the undercut space UC. Specifically, each of the light emitting layer EML and the common electrode CE may be disconnected on the second inclined surface AE3-2 of the third auxiliary electrode AE3.

As mentioned above, the third auxiliary electrode AE3 may cover the second auxiliary electrode AE2 exposed by the first through-hole H1 and a portion of the interlayer insulating layer ILD. In addition, the passivation layer PVX in which a second through-hole H2 is defined may be disposed on the third auxiliary electrode AE3. Accordingly, the undercut space UC may include a sufficient space for the common electrode CE to contact the third auxiliary electrode AE3.

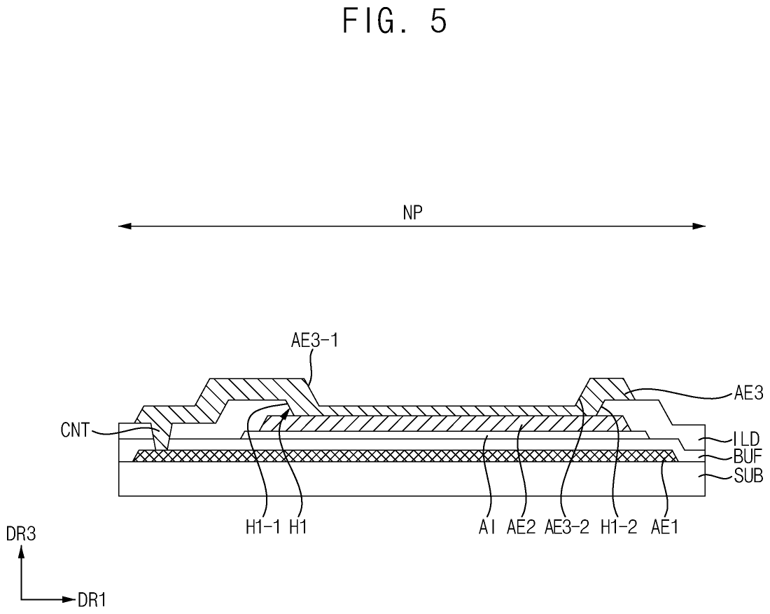

In an embodiment, the second side area H2-2 of the second through-hole H2 may be disposed further away from a virtual line VL which intersects a central portion of the first through-hole H1 than the first side area H2-1 of the second through-hole H2. This may be because, as will be described later with reference to FIGS. 5, 6, 7, 8, 9, and 10, a portion of the passivation layer PVX is removed through an etching process using the pixel defining layer PDL as a mask. In addition, the first side area H2-1 of the second through-hole H2 may be disposed closer to the virtual line VL than the first side area H1-1 of the first through-hole H1.

In an embodiment, the second side area H3-2 of the third through-hole H3 may be disposed further away from the virtual line VL than the first side area H3-1 of the third through-hole H3. In addition, the first side area H3-1 of the third through-hole H3 may be disposed closer to the virtual line VL than the first side area H2-1 of the second through-hole H2. This may be to prevent the first side area H2-1 of the passivation layer PVX from being removed when the etching process is performed using the pixel defining layer PDL as a mask. Accordingly, each of the light emitting layer EML disposed on the pixel defining layer PDL and the common electrode CE disposed on the pixel defining layer PDL may contact the third auxiliary electrode AE3 in the undercut space UC.

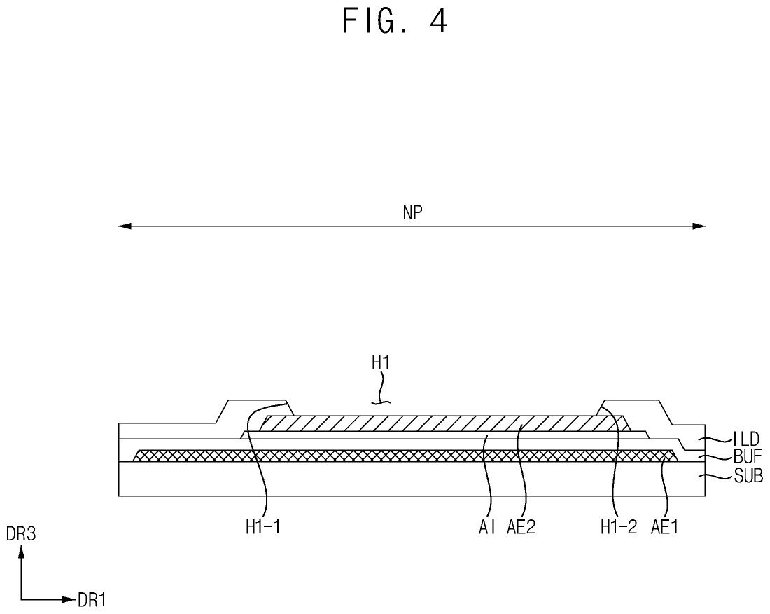

FIGS. 4, 5, 6, 7, 8, 9, and 10 are schematic cross-sectional views illustrating a method of manufacturing the display device of FIG. 1. Specifically, FIGS. 4, 5, 6, 7, 8, 9, and 10 are schematic cross-sectional views illustrating a method of manufacturing a non-light emitting area of the display device of FIG. 1.

Referring to FIG. 4, the first auxiliary electrode AE1 may be formed on the substrate SUB. The buffer layer BUF may be formed on the first auxiliary electrode AE1. The auxiliary electrode insulating layer AI may be formed on the buffer layer BUF. The second auxiliary electrode AE2 may be formed on the auxiliary electrode insulating layer AI. A preliminary interlayer insulating layer (not shown) may be formed on the second auxiliary electrode AE2.

The interlayer insulating layer ILD including the first through-hole H1 may be formed by removing a portion of the preliminary interlayer insulating layer. In an embodiment, the portion of the preliminary interlayer insulating layer may be removed through an etching process. The first through-hole H1 may expose at least a portion of the second auxiliary electrode AE2. In addition, the first through-hole H1 may include the first side area H1-1 and the second side area H1-2.

Referring to FIG. 5, the third auxiliary electrode AE3 may be formed on the second auxiliary electrode AE2. Specifically, the third auxiliary electrode AE3 may cover the second auxiliary electrode AE2 exposed by the first through-hole H1 and the portion of the interlayer insulating layer ILD. In addition, the contact hole CNT formed through the interlayer insulating layer ILD and the buffer layer BUF may be formed. The third auxiliary electrode AE3 and the first auxiliary electrode AE1 may be connected through the contact hole CNT. The third auxiliary electrode AE3 may include the first inclined surface AE3-1 and the second inclined surface AE3-2.

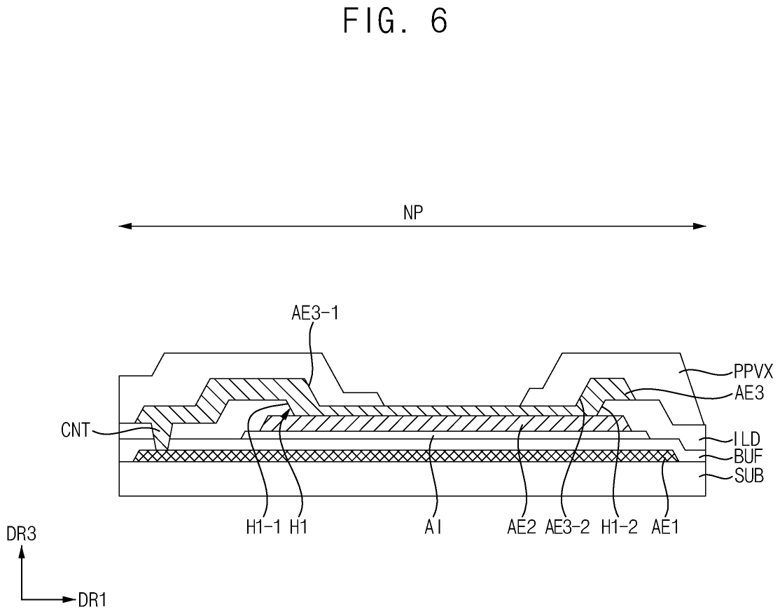

Referring to FIG. 6, a preliminary passivation layer PPVX from which a central portion is removed may be disposed on the third auxiliary electrode AE3. A portion of the third auxiliary electrode AE3 may be exposed through the central portion.

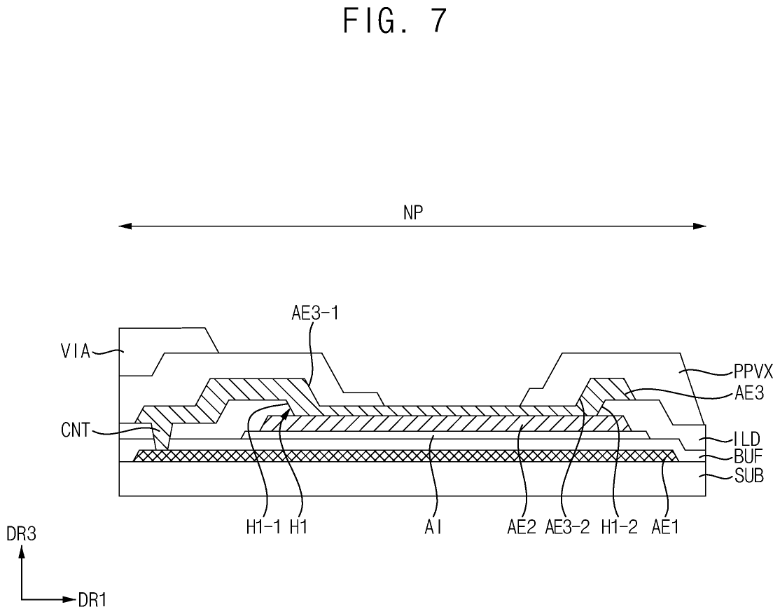

Referring to FIG. 7, the via insulating layer VIA may be formed on a portion of the preliminary passivation layer PPVX.

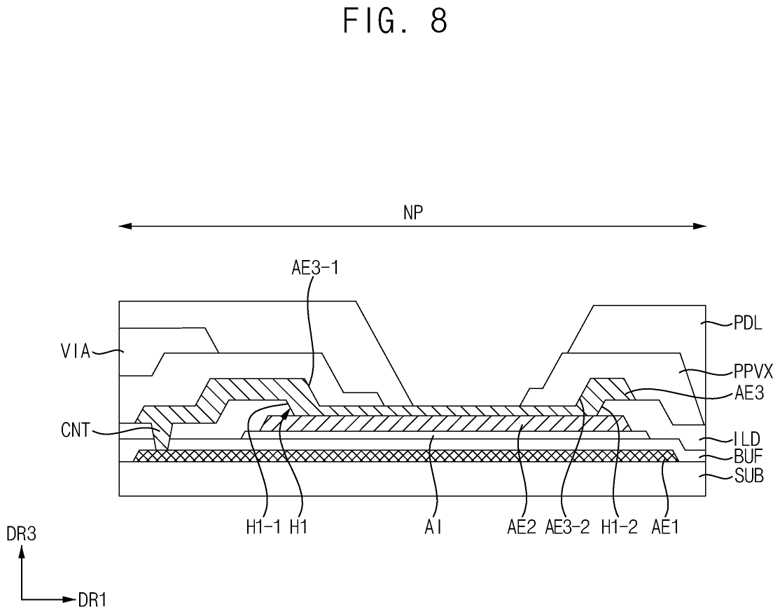

Referring to FIG. 8, a preliminary pixel defining layer (not shown) may be formed on the preliminary passivation layer PPVX. A portion of the preliminary pixel defining layer may be removed to expose a portion of the third auxiliary electrode AE3 and a portion of the preliminary passivation layer PPVX.

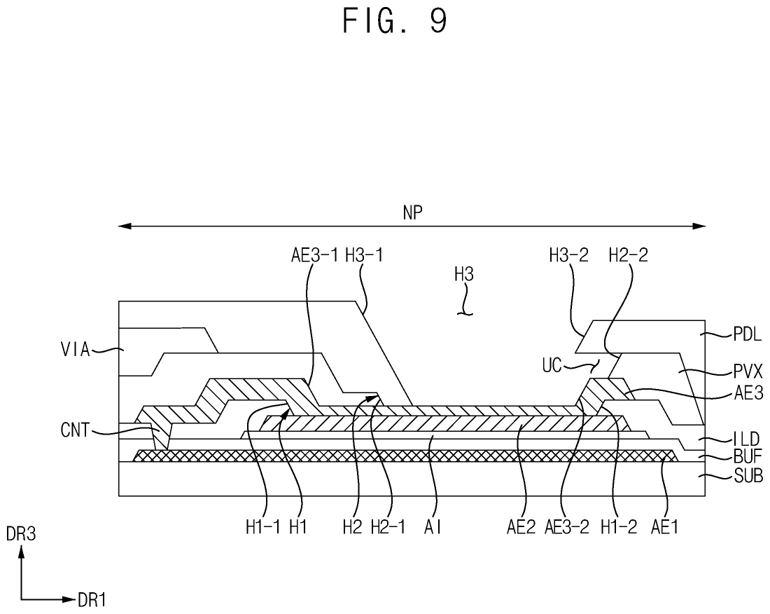

Referring to FIGS. 8 and 9, a portion of the preliminary passivation layer PPVX may be removed to form a passivation layer PVX including a second through-hole H2, a pixel defining layer PDL including a third through-hole H3, and an undercut space UC. Specifically, the portion of the passivation layer PVX may be removed through an etching process using the pixel defining layer PDL as an etching mask. In an embodiment, the etching process may be a wet etching process.

The second through-hole H2 may include the first side area H2-1 which is covered by the pixel defining layer PDL, the second side area H2-2 which is not covered by the pixel defining layer PDL. In addition, the undercut space UC may be disposed under the second side area H3-2 of the pixel defining layer PDL. For example, the undercut space UC may be a space formed by a lower surface of the pixel defining layer PDL, the second side area H2-2 of the passivation layer PVX, and an upper surface of the third auxiliary electrode AE3. In addition, the third through-hole H3 may include the first side area H3-1 and the second side area H3-2.

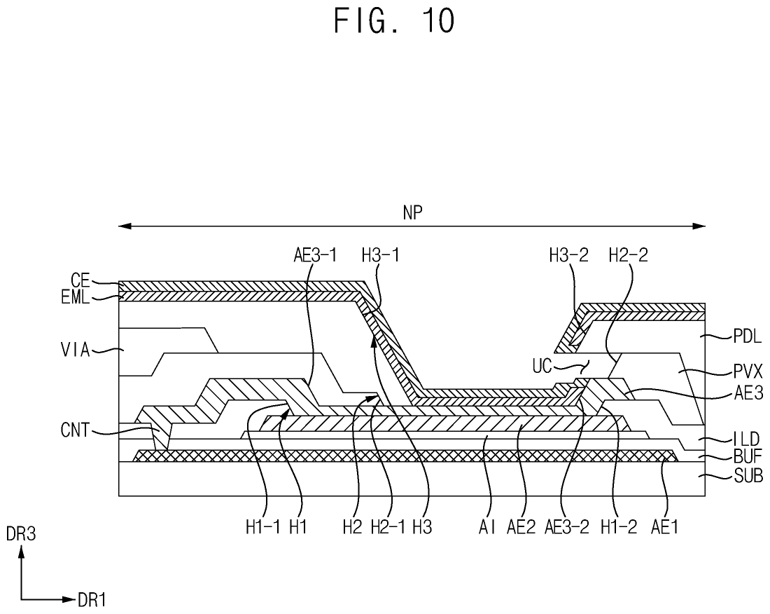

Referring to FIG. 10, the light emitting layer EML may be formed on the pixel defining layer PDL. Specifically, the light emitting layer EML may be formed along the first side area H3-1 of the third through-hole H3 to the second inclined surface AE3-2 of the third auxiliary electrode AE3. That is, the light emitting layer EML may be disconnected on the second inclined surface AE3-2 of the third auxiliary electrode AE3.

The common electrode CE may be formed on the light emitting layer EML. In an embodiment, the common electrode CE may be disposed to contact the second inclined surface AE3-2 of the third auxiliary electrode AE3. That is, the common electrode CE may be disconnected on the second inclined surface AE3-2 of the third auxiliary electrode AE3.

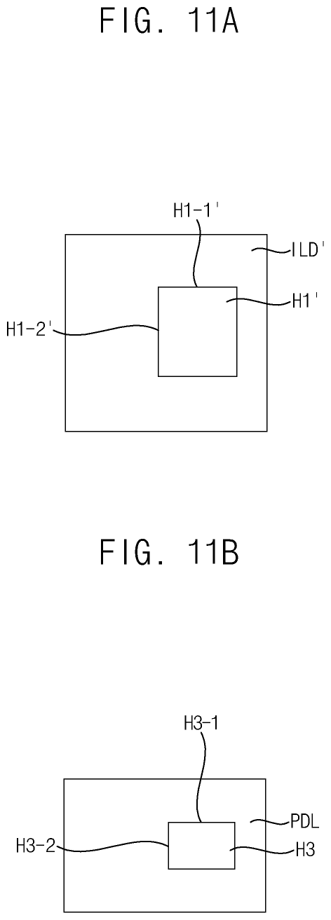

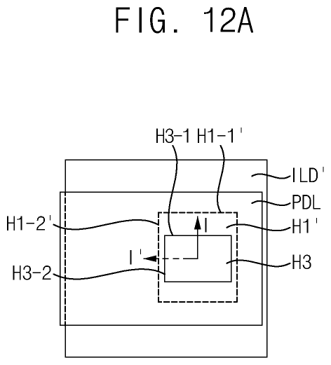

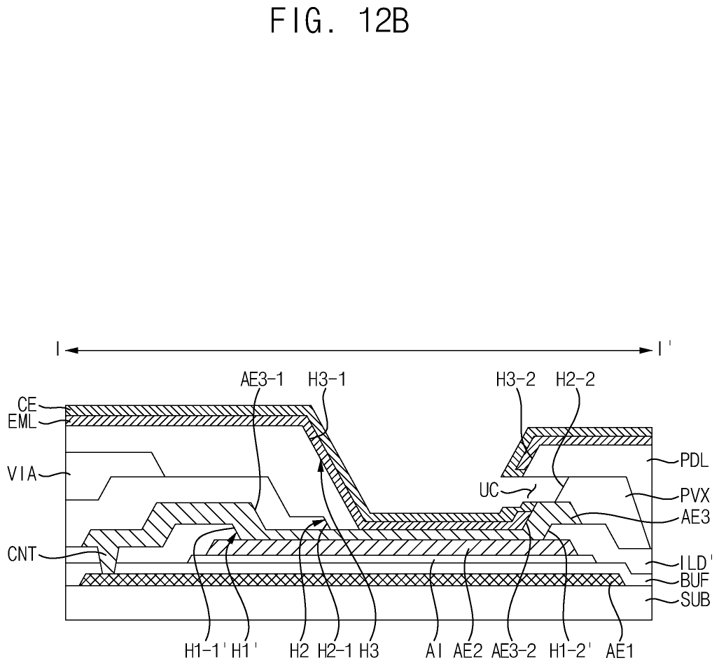

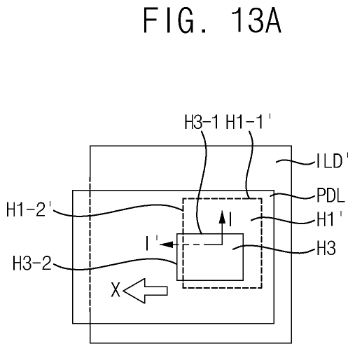

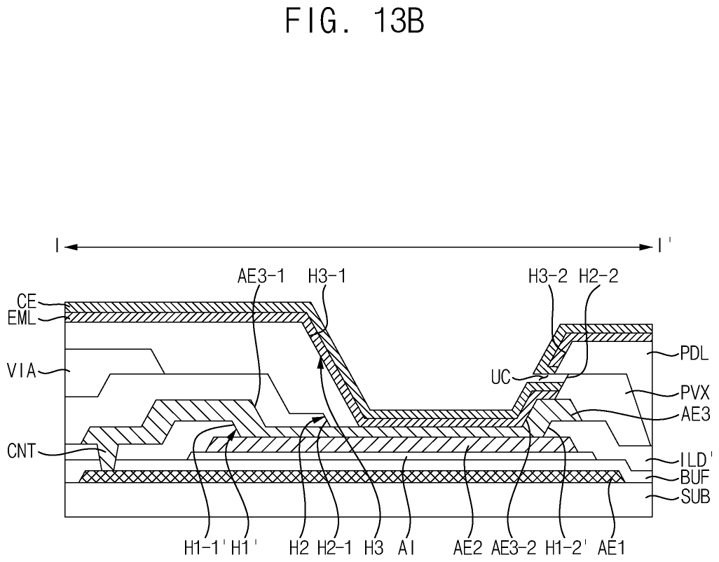

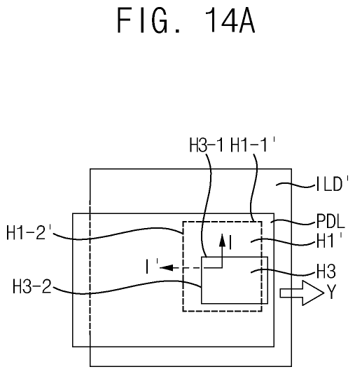

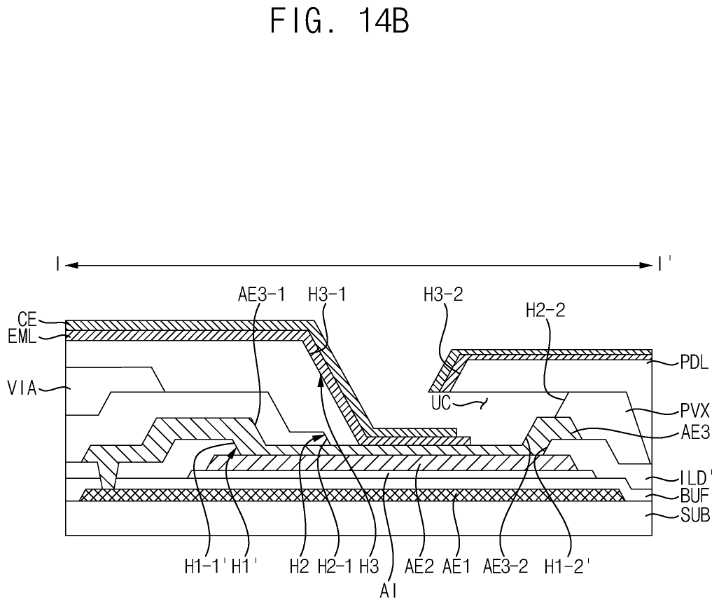

FIG. 11A is a schematic plan view of an interlayer insulating layer according to a comparative example. FIG. 11B is a schematic plan view illustrating a pixel defining layer of FIG. 2. FIG. 12A is a schematic plan view illustrating a first relative position of the pixel defining layer of FIG. 11B and the interlayer insulating layer according to comparative example. FIG. 12B is a schematic cross-sectional view of display device cut along the I-I′ line of FIG. 12A. FIG. 13A is a schematic plan view illustrating a second relative position of the pixel defining layer of FIG. 11B and the interlayer insulating layer according to comparative example. FIG. 13B is a schematic cross-sectional view of display device cut along the I-I′ line of FIG. 13A. FIG. 14A is a schematic plan view illustrating a third relative position of the pixel defining layer of FIG. 11B and the interlayer insulating layer according to comparative example. FIG. 14B is a schematic cross-sectional view of display device cut along the I-I′ line of FIG. 14A.

Referring to FIG. 11A, an interlayer insulating layer ILD′ may include a first through-hole H1′. The first through-hole H1′ may include a first side area H1-1′ and a second side area H1-2.

Referring to FIG. 11B, the pixel defining layer PDL may include a third through-hole H3. The third through-hole H3 may include the first side area H3-1 and the second side area H3-2.

Referring to FIGS. 11A, 11B, 12A, and 12B, FIG. 12A may indicate that the pixel defining layer PDL is disposed on the interlayer insulating layer ILD′ in a plan view. Specifically, FIG. 12A may indicate that the pixel defining layer PDL is correctly aligned on the interlayer insulating layer ILD′. “Correctly aligned” here may mean that the undercut space UC is sufficiently secured as shown in FIG. 12B, so that the common electrode CE may contact the third auxiliary electrode AE3.

When manufacturing process of the display device (e.g., the display device DD of FIG. 1) is performed several times, the pixel defining layer PDL may be incorrectly aligned on the interlayer insulating layer ILD′. For example, FIG. 13A may indicate that the third through-hole H3 of the pixel defining layer PDL is shifted in a negative direction X as compared to FIG. 12A. In addition, FIG. 14A may indicate that the third through-hole H3 of the pixel defining layer PDL is shifted in a positive direction Y as compared to FIG. 12A.

Referring to FIGS. 12A, 12B, 13A, and 13B, according to FIG. 13A, when the pixel defining layer PDL is disposed on the interlayer insulating layer ILD′ so that the third through-hole H3 is moved in the negative direction X as compared to FIG. 12A, the common electrode CE may contact the passivation layer PVX as shown FIG. 13B. That is, the common electrode CE may not be in contact with the third auxiliary electrode AE3.

Referring to FIGS. 12A, 12B, 14A, and 14B, according to FIG. 14A, when the pixel defining layer PDL is disposed on the interlayer insulating layer ILD′ so that the third through-hole H3 is moved in the positive direction Y as compared to FIG. 12A, the common electrode CE may not contact the third auxiliary electrode AE3 as shown FIG. 14B.

That is, the second side area H1-2′ of the first through-hole H1′ according to the comparative example may be disposed in parallel to the second side area H3-2 of the third through-hole H3. Accordingly, when the pixel defining layer PDL is misaligned to the interlayer insulating layer ILD′, the common electrode CE may not be in contact with the third auxiliary electrode AE3.

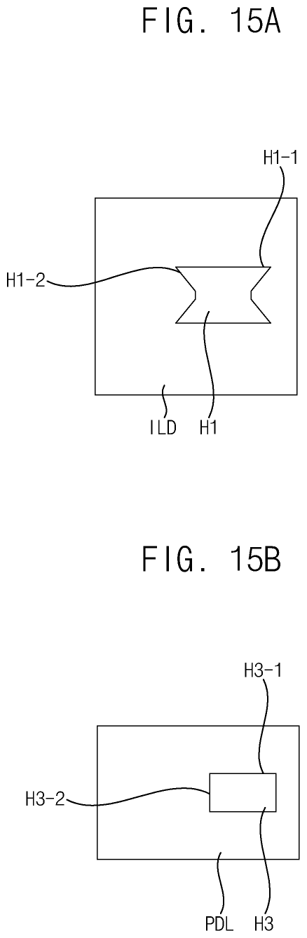

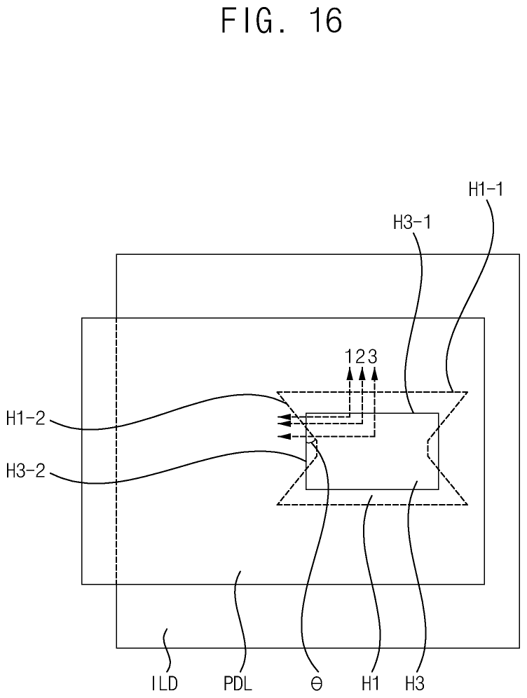

FIG. 15A is a schematic plan view illustrating an interlayer insulating layer according to an embodiment. FIG. 15B is a schematic plan view illustrating a pixel defining layer according to an embodiment. FIG. 16 is a schematic plan view illustrating that the pixel defining layer of FIG. 15B is disposed on the interlayer insulating layer of FIG. 15A.

Referring to FIGS. 15A, 15B, and 16, The second side area H1-2 of the first through-hole H1 according to an embodiment may intersect the second side area H3-2 of the third through-hole H3 at a predetermined angle θ in a plan view. In an embodiment, the predetermined angle θ may be an acute angle.

Accordingly, even if the pixel defining layer PDL is misaligned to the interlayer insulating layer ILD, the common electrode CE may contact the third auxiliary electrode AE3. That is, regardless of the relative position of the interlayer insulating layer ILD and the pixel defining layer PDL, the common electrode CE may contact the third auxiliary electrode AE3.

For example, a cross-sectional view of the display device (e.g., the display device DD of FIG. 1) along a first line 1 may be the same as FIG. 14B. In addition, a cross-sectional view of the display device cut along a second line 2 may be the same as FIG. 12B. In addition, a cross-sectional view of the display device cut along a third line 3 may be the same as FIG. 13B.

In other words, when the second side area H1-2 of the first through-hole H1 intersects the second side area H3-2 of the third through-hole H3 at a certain angle θ in a plan view, there must be an area in which the common electrode CE contacts the third auxiliary electrode AE3, such as the cross-sectional view cut along the second line 2.

Accordingly, the common electrode CE may be ultimately connected to the first auxiliary electrode AE1, and thus resistance of the common electrode CE may be reduced. Accordingly, a voltage drop phenomenon of the common electrode may be prevented.

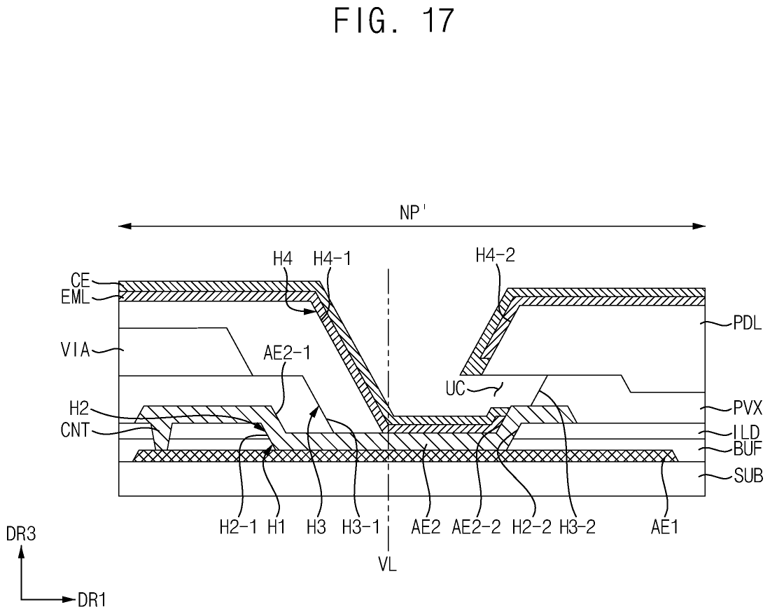

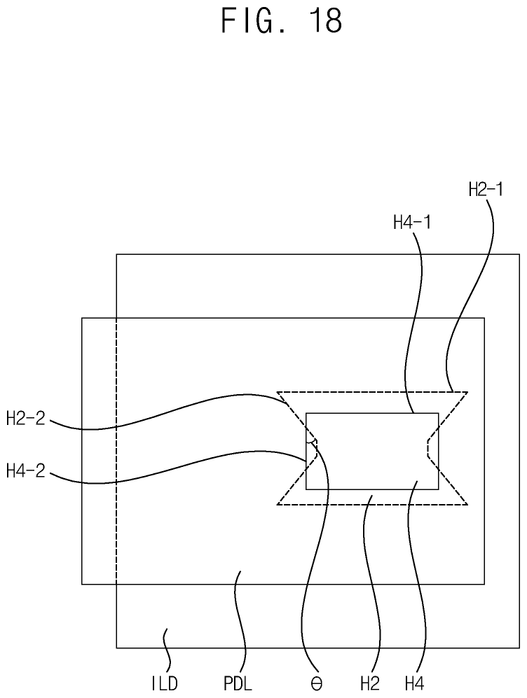

FIG. 17 is a schematic cross-sectional view illustrating a non-light emitting area of a display device according to another embodiment.

In describing the non-light emitting area NP′ of the display device according to another embodiment of FIG. 17, a detailed description of substantially the same components as the non-light emitting area NP of the display device of FIG. 3 may be omitted.

Referring to FIG. 17, a substrate SUB, a first auxiliary electrode AE1, a buffer layer BUF, a second auxiliary electrode AE2, an interlayer insulating layer ILD, a passivation layer PVX, a pixel defining layer PDL, a contact hole CNT, a light emitting layer EML, and a common electrode CE may be disposed in the non-light emitting area NP′ according to another embodiment.

The first auxiliary electrode AE1 may be disposed on the substrate SUB. The first auxiliary electrode AE1 may include the same material as the light blocking layer (e.g., the light blocking layer LS of FIG. 2) of the light emitting area (e.g., the light emitting area EP of FIG. 2), and may be formed through the same process as the light blocking layer of the light emitting area. The first auxiliary electrode AE1 may be a portion of a power supply voltage line (not shown). Specifically, the first auxiliary electrode AE1 may be a portion of ELVSS line.

The buffer layer BUF may be disposed on the first auxiliary electrode AE1. The buffer layer BUF may sufficiently cover the first auxiliary electrode AE1. The buffer layer BUF may include a first through-hole H1. The first through-hole H1 may expose at least a portion of the first auxiliary electrode AE1. For example, the first through-hole H1 may expose a central portion of the first auxiliary electrode AE1.

The interlayer insulating layer ILD may be disposed on the buffer layer BUF. The interlayer insulating layer ILD may include a second through-hole H2. The second through-hole H2 may overlap the first through-hole H1.

The second-through-hole H2 may include a first side area H2-1 and a second side area H2-2. The second side area H2-2 may partially overlap an undercut space UC to be described later.

The second auxiliary electrode AE2 may cover the first auxiliary electrode AE1 exposed by the first through-hole H1 and the second through-hole H2, a portion of the buffer layer BUF, a portion of the interlayer insulating layer ILD. For example, the second auxiliary electrode AE2 may cover a portion of the buffer layer BUF and a portion of the interlayer insulating layer ILD disposed adjacent to the first auxiliary electrode AE1 exposed by the first through hole H1 and the second through hole H2. The second auxiliary electrode AE2 may include a first inclined surface AE2-1 and a second inclined surface AE2-2. The second inclined surface AE2-2 may partially overlap the undercut space UC.

The second auxiliary electrode AE2 may include the same material as the source electrode (e.g., the source electrode SE of FIG. 2) and the drain electrode (e.g., the drain electrode DE of FIG. 2) of the light emitting area, and may be formed through the same process as the source electrode and the drain electrode. The second auxiliary electrode AE2 may be connected to the first auxiliary electrode AE1 through the contact hole CNT formed through the buffer layer and the interlayer insulating layer ILD.

The passivation layer PVX may be disposed on the second auxiliary electrode AE2. The passivation layer PVX may include a third through-hole H3. The third through-hole H3 may expose at least a portion of the second auxiliary electrode AE2. The third through-hole H3 may include a first side area H3-1 and a second side area H3-2. The second side area H3-2 may be exposed by the undercut space UC.

The via insulating layer VIA may be disposed on the passivation layer PVX. For example, the via insulating layer VIA may be disposed at a portion overlapping the contact hole CNT on the passivation layer PVX.

The pixel defining layer PDL may be disposed on the passivation layer PVX and the via insulating layer VIA. The pixel defining layer PDL may define a fourth through-hole H4. The fourth through-hole H4 may include a first side area H4-1 and a second side area H4-2.

The undercut space UC may be defined by the second side area H3-2 of the third through-hole H3 and a lower surface of the pixel defining layer PDL in the third through-hole H2. For example, the undercut space UC may be a space formed by the lower surface of the pixel defining layer PDL, the second side area H3-2 of the passivation layer PVX, and an upper surface of the second auxiliary electrode AE2. The undercut space UC may expose the second side area H3-2 of the passivation layer PVX.

The light emitting layer EML may be disposed on the pixel defining layer PDL and the second auxiliary electrode AE2. A portion of the light emitting layer EML overlapping the non-light emitting area NP may include the hole injection layer, the hole transport layer disposed on the hole injection layer, the electron transport layer disposed on the hole transport layer, and the electron injection layer disposed on the electron transport layer.

The common electrode CE may be disposed on the light emitting layer EML. A space in which the common electrode CE contacts the second auxiliary electrode AE2 may be formed through the undercut space UC. Specifically, the common electrode CE may be in contact with the second inclined surface AE2-2 of the second auxiliary electrode AE2.

In an embodiment, each of the light emitting layer EML and the common electrode CE may be disconnected in the undercut space UC. Specifically, each of the light emitting layer EML and the common electrode CE may be disconnected on the second inclined surface AE2-2 of the second auxiliary electrode AE2.

As mentioned above, the second auxiliary electrode AE2 may cover the first auxiliary electrode AE1 exposed by the first through-hole H1 and the second through-hole H2, a portion of the buffer layer BUF, a portion of the interlayer insulating layer ILD. In addition, the passivation layer PVX in which a third through-hole H3 is defined may be disposed on the second auxiliary electrode AE2. Accordingly, the undercut space UC may include a sufficient space for the common electrode CE to contact the second auxiliary electrode AE2.

In an embodiment, the second side area H3-2 of the third through-hole H3 may be disposed further away from a virtual line VL intersecting a central portion of the first through-hole H1 than the first side area H3-1 of the third through-hole H3. In addition, the first side area H3-1 of the third through-hole H3 may be disposed closer to the virtual line VL than the first side area H2-1 of the second through-hole H2.

In an embodiment, the second side area H4-2 of the fourth through-hole H4 may be disposed further away from the virtual line VL than the first side area H4-1 of the fourth through-hole H4. In addition, the first side area H4-1 of the fourth through-hole H4 may be disposed closer to the virtual line VL than the first side area H3-1 of the third through-hole H3. This may be to prevent the first side area H3-1 of the passivation layer PVX from being removed when an etching process is performed using the pixel defining layer PDL as a mask. Accordingly, the light emitting layer EML and the common electrode CE disposed on the pixel defining layer PDL may contact the second auxiliary electrode AE2 in the undercut space UC.

FIG. 18 is a schematic plan view illustrating an interlayer insulating layer and a pixel defining layer of FIG. 17.

Referring to FIG. 18, the second side area H2-2 of the second through-hole H2 according to another embodiment may intersect the second side area H4-2 of the fourth through-hole H4 while forming a predetermined angle θ in a plane view. In an embodiment, the predetermined angle θ may be an acute angle.

The present disclosure can be applied to various display devices. For example, the present disclosure is applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A display device comprising:
a first auxiliary electrode;
a second auxiliary electrode disposed on the first auxiliary electrode;
an interlayer insulating layer disposed on the second auxiliary electrode, exposing at least a portion of the second auxiliary electrode, and including a first through-hole which includes a first side area and a second side area;
a third auxiliary electrode covering the second auxiliary electrode exposed by the first through-hole and a portion of the interlayer insulating layer, the third auxiliary electrode including a first inclined surface and a second inclined surface;
a passivation layer disposed on the third auxiliary electrode, exposing at least a portion of the third auxiliary electrode, and including a second through-hole which includes a first side area and a second side area;
a pixel defining layer disposed on the passivation layer and including a third through-hole, the third through-hole including a first side area and a second side area;
a light emitting layer disposed on the pixel defining layer and the third auxiliary electrode; and
a common electrode disposed on the light emitting layer,
wherein an undercut space is defined by the second side area of the second through-hole and a lower surface of the pixel defining layer in the second through-hole,
wherein the common electrode is electrically connected to the third auxiliary electrode in the undercut space,
wherein the second side area of the first through-hole, the second side area of the second through-hole, the second side area of the third through-hole, and the second inclined surface of the third auxiliary electrode partially overlap the undercut space.

2. The display device of claim 1, wherein the second side area of the second through-hole is disposed further away from a central portion of the first through-hole than the first side area of the second through-hole.

3. The display device of claim 1, wherein the first side area of the second through-hole is disposed closer to a central portion of the first through-hole than the first side area of the first through-hole.

4. The display device of claim 1, wherein the second side area of the third through-hole is disposed further away from a central portion of the first through-hole than the first side area of the third through-hole.

5. The display device of claim 1, wherein the first side area of the third through-hole is disposed closer to a central portion of the first through-hole than the first side area of the second through-hole.

6. The display device of claim 1, wherein the second side area of the first through-hole intersects the second side area of the third through-hole in a plan view.

7. The display device of claim 6, wherein the second side area of the first through-hole intersects the second side area of the third through-hole in an acute angle in a plan view.

8. The display device of claim 1, further comprising:
a buffer layer disposed between the first auxiliary electrode and the second auxiliary electrode.

9. The display device of claim 8, further comprising:
an auxiliary electrode insulating layer disposed between the buffer layer and the second auxiliary electrode.

10. The display device of claim 9, wherein the third auxiliary electrode and the first auxiliary electrode are connected to each other by a contact hole.

11. The display device of claim 1, wherein the common electrode is in contact with the second inclined surface of the third auxiliary electrode.

12. A display device comprising:
a first auxiliary electrode;
a buffer layer including a first through-hole exposing at least a portion of the first auxiliary electrode;
an interlayer insulating layer disposed on the buffer layer, including a second through-hole overlapping the first through-hole, wherein the second through-hole has a first side area and a second side area;
a second auxiliary electrode covering the first auxiliary electrode exposed by the first through-hole and the second through-hole, a portion of the buffer layer, and a portion of the interlayer insulating layer, wherein the second auxiliary electrode includes a first inclined surface and a second inclined surface;
a passivation layer disposed on the second auxiliary electrode, exposing at least a portion of the second auxiliary electrode, and including a third through-hole which includes a first side area and a second side area;
a pixel defining layer disposed on the passivation layer, including a fourth through-hole, the fourth through-hole including a first side area and a second side area;
a light emitting layer disposed on the pixel defining layer and the second auxiliary electrode; and
a common electrode disposed on the light emitting layer,
wherein the undercut space is defined by the second side of the third through-hole and a lower surface of the pixel defining layer in the third through-hole,
wherein the common electrode is electrically connected to the second auxiliary electrode in the undercut space,
wherein the second side area of the first through-hole, the second side area of the second through-hole, the second side area of the third through-hole, the second side area of the fourth through-hole, and the second inclined surface of the second auxiliary electrode partially overlap the undercut space.

13. The display device of claim 12, wherein the second side area of the third through-hole is disposed further from a central portion of the first through-hole than the first side area of the third through-hole.

14. The display device of claim 12, wherein the first side area of the third through-hole is disposed closer to a central portion of the first through-hole than the first side area of the second through-hole.

15. The display device of claim 12, wherein the second side area of the fourth through-hole is disposed further from a central portion of the first through-hole than the first side area of the fourth through-hole.

16. The display device of claim 12, wherein the first side area of the fourth through-hole is disposed closer to a central portion of the first through-hole than the first side area of the third through-hole.

17. The display device of claim 12, wherein the second side area of the second through-hole intersects the second side area of the fourth through-hole in a plan view.

18. The display device of claim 17, wherein the second side area of the second through-hole intersects the second side area of the fourth through-hole in an acute angle in a plan view.

19. The display device of claim 12, wherein the common electrode is in contact with the second inclined surface of the second auxiliary electrode.

20. The display device of claim 12, wherein the first auxiliary electrode and the second auxiliary electrode are connected to each other by a contact hole.
